(19) United States
(12) Patent Application Publication
(10) Pub. No.: US 2014/0175279 A1
(43) Pub. Date: Jun. 26, 2014

(54) CHARGED PARTICLE BEAM APPARATUS

(71) Applicant: Toshihide Agemura, Tokyo (JP)

(72) Inventor: Toshihide Agemura, Tokyo (JP)

(73) Assignee: HITACHI HIGH-TECHNOLOGIES CORPORATION, Tokyo (JP)

(21) Appl. No.: 14/233,124

(22) PCT Filed: Jul. 25, 2012
(86) PCT No.: PCT/JP2012/068754

§ 371 Date: Jan. 15, 2014

(30) Foreign Application Priority Data
Aug. 3, 2011 (JP) 2011-169735

(51) Int. Cl. H01J 37/244; H01J 37/28

(52) U.S. Cl. CPC H01J 37/244; H01J 37/28
USPC 250/310

(57) ABSTRACT

A charged particle beam apparatus that easily discriminates the angles and energy of the SE or the BSE, and images information necessary for a sample to be observed.

The charged particle beam apparatus having a charged particle source that emits a primary charged particle beam, a condenser lens that condenses the primary charged particle beam on a sample, and a detector that detects secondary charged particles emitted from a radiated point on the sample, the charged particle beam apparatus including: a pulse processing unit that subjects a signal from the detector to pulse processing, and creates energy distribution information of the secondary charged particles; and a control unit that selects information in an arbitrary energy region of the energy distribution information, and display an image on a display unit.

### TECHNICAL FIELD

The present invention relates to a charged particle beam apparatus, and more particularly to a detector and a detecting method for secondary charged particles in a charged particle beam apparatus for observing a sample through a scanning electron beam.

### BACKGROUND ART

In recent years, scanning electron microscopes (SEM) have been used to observe a surface or a cross-section of target samples in extensive fields. The SEM detects secondary electrons (SE) having a relatively low energy of 0 to 50 eV, which are generated by an interaction of a primary electron beam and the sample, and backscattered electrons (BSE) having an extensive distribution from 50 eV to an energy of the primary electron beam for imaging.

There has been generally known that obtained information is different according to respective energy regions detected by the SE and the BSE. For example, SE having several of eV reflects sample surface or topographic information, and the SE having a more energy reflects sample internal information, and may also reflect electrical potential information on the sample surface. The BSE reflects compositional information or crystalline information on the sample, and the sample internal information deeper than that of the SE. Also, low loss electrons (LLE) particularly scattered on the sample surface among the BSE includes not only compositional information, but reflects information on the sample surface.

In the current SEM, a relationship (generally called “acceptance”) of energy distributions of the SE and the BSE, an angle distribution when emitted from the sample, and a detector/detection system are important elements for obtaining the above necessary information. For that reason, in the marketed SEM, the detector for detecting the SE or the BSE, or the detection system combining an optical system with the detector have been frequently devised up to now, and a large number of systems has been proposed.

It is very difficult to detect the energy distribution while changing a threshold on a higher energy side of the energy distributions of the SE and the BSE. For example, in Patent Literature 1, because the energy distribution of signal electrons such as reflected electrons or secondary electrons generated when the primary electron beam is irradiated to the sample is displayed as an image, a voltage applied to a signal detector is changed to detect the signal electrons. However, a threshold on a lower energy side is merely changed. Also, most of the thresholds of the lower energy are unambiguously determined according to physical characteristics (an energy region detectable by the detector) of the detector except for a detector combined with an energy filter. Exceptionally, in an example such as an Auger spectroscopy, the energy threshold of a bandpass can be set with the use of a semispherical energy analyzer or a cylindrical mirror energy analyzer. However, the device is massive and expensive, and not applied in the marketed conventional SEM.

In the angle distribution, a detector element per se is divided, or a height of the sample is adjusted to change an solid angle to the detector, thereby adjusting a detection angle of emitted electrons. In particular, in the BSE detection, only the BSE having a specific angle range can be detected. On the other hand, the energy distribution of the SE and the BSE detected in the specific angle range is not found.

In the conventional SEM, signal processing after the SE or the BSE has been detected includes any one of processing a detection signal as an analog signal, and processing the detection signal as a pulse signal captured as the number of electrons input to the detector.

### CITATION LIST

### Patent Literature

Patent Literature 1: Japanese Unexamined Patent Application Publication No. 2005-004995

### SUMMARY OF INVENTION

### Technical Problem

As described above, in the conventional SEM, an energy region is arbitrarily set, and emitted electrons within the region cannot be imaged.

An object of the present invention is to provide an charged particle beam apparatus that easily discriminates the angles and energy of the SE or the BSE, and images information necessary for a sample to be observed.

### Solution to Problem

According to the present invention, there is provided a charged particle beam apparatus having a charged particle source that emits a primary charged particle beam, a condenser lens that focuses the primary charged particle beam on a sample, and a detector that detects secondary charged particles emitted from a radiated point on the sample, the charged particle beam apparatus including: a pulse processing unit that subjects a signal from the detector to pulse processing, and creates energy distribution information of the secondary charged particles; and a control unit that selects information in an arbitrary energy region of the energy distribution information, and display an image on a display unit.

### Advantageous Effects of Invention

The SE or the BSE reflects the sample surface or the topographic information, voltage potential information on the sample surface, compositional or crystalline information on the sample, and the sample internal information according to the energy or emitted angle of the electrons. Therefore, the relationship (acceptance) of the energy distributions of the SE and the BSE, the angle distribution when emitted from the sample, and the detector/detection system are important elements for obtaining those information. According to the present invention, there is provided the SEM device that easily discriminates the angles and energy of the SE or the BSE for imaging, which can discriminate the SE or BSE having a specific energy or energy which is arbitrarily settable, and visualize really necessary information on a sample to be observed, and dramatically improves physical phenomenon elucidation of the sample to be observed by a user, and the convenience.

### BRIEF DESCRIPTION OF DRAWINGS

FIG. 1 is a schematic view of a scanning electron microscope (SEM) according to the present invention.

FIG. 2 is a relationship diagram of an energy of emitted electrons and an electron yield.

FIG. 3 is a diagram illustrating characteristics of various detectors.

FIG. 4 is a schematic view of the scanning electron microscope (SEM) (having an ET detector).

FIG. 5 is a relationship diagram of the energy, the electron yield, and an energy sensitivity of the ET detector.

FIG. 6 is a schematic view of the scanning electron microscope (SEM) (having an energy filter) according to the present invention.

FIG. 7 is a schematic view of the scanning electron microscope (SEM) (having a semi-in-lens and an electrode) according to the present invention.

FIG. 8 is a relationship diagram of the energy of the emitted electrons and the electron yield (emitted electrons detected by the scanning electron microscope in FIGS. 6 and 7).

FIG. 9 is a schematic view of the scanning electron microscope (SEM) (with the application of a positive bias voltage to the sample) according to the present invention.

FIG. 10 is a relationship diagram of the energy of the emitted electrons and the electron yield (after energy shift).

FIG. 11 is a schematic view of the scanning electron microscope (SEM) (having a pulse processing unit and a control PC in the ET detector of FIG. 4) according to the present invention.

FIG. 12 is a schematic view of the scanning electron microscope (SEM) (with the provision of a semi-in-lens and the application of a negative bias voltage to the sample) according to the present invention.

FIG. 13 is a schematic view of the scanning electron microscope (SEM) (having a beam booster electrode) according to the present invention.

FIG. 14 is a relationship diagram of the energy of the emitted electrons and the electron yield (with the setting of a region of interest after shifting to a higher energy side).

FIG. 15a is a relationship diagram of the energy, the electron yield, and an X-ray count.

FIG. 15b is a relationship diagram of the energy, the electron yield, and the X-ray count (having the beam booster electrode of FIG. 13).

FIG. 16 illustrates an example of an area divided detector.

### DESCRIPTION OF EMBODIMENTS

Hereinafter, embodiments will be described with reference to the drawings.

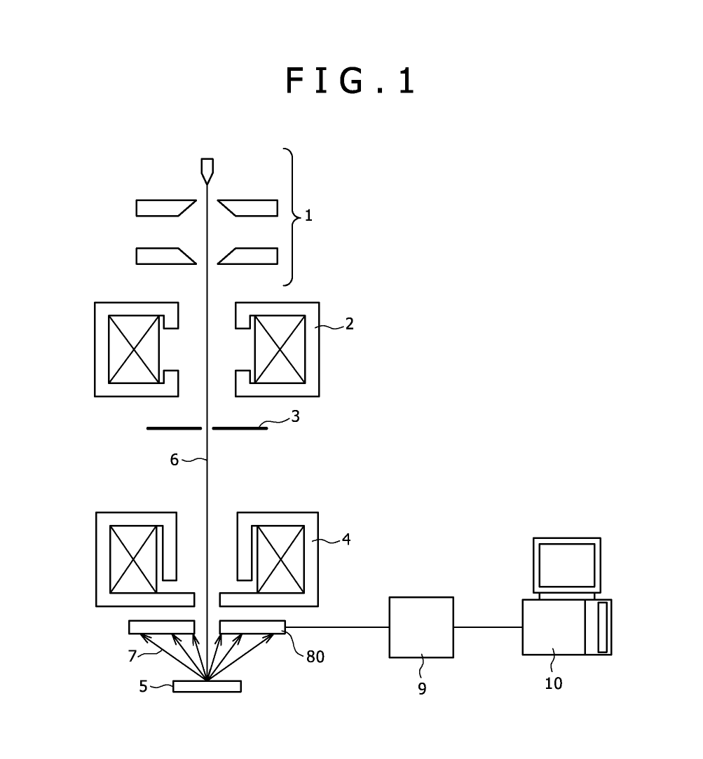

FIG. 1 is a schematic view of a scanning electron microscope (SEM) according to the present invention.

An electron gun 1 takes a primary electron beam 6 from an electron source, and accelerates the primary electron beam 6 up to an energy set by a user. A condenser lens 2 controls a probe current quantity of the primary electron beam 6 and a convergence angle of the primary electron beam 6 to a sample according to a relationship with an aperture 3 or an objective lens 4. The objective lens 4 focuses the primary electron beam 6 on a sample 5. When the sample 5 is irradiated with the primary electron beam 6, emitted electrons 7 are emitted depending on an energy thereof at the time of irradiation, and a composition, a crystalline property, a sample voltage potential, a topographic property, a sample thickness, and a sample inclined angle (convergence angle of the primary electron beam 6 to the sample 5) of the sample 5.

The emitted electrons 7 are detected by a detector 80 arranged coaxially with an optical axis of the primary electron beam 6, and just below the objective lens 4, and an electric signal is output from the detector 80. The electric signal output from the detector 80 is input to a pulse processing unit 9, and the electric signal is subjected to pulse shape processing, and pulse discrimination processing, and the number of counts is accumulated in a channel of each energy of the emitted electrons 7. The detector 80 outputs a pulse signal higher in pulse height as the energy of the emitted electrons 7 is larger, and outputs a larger number of pulse signals as the number of emitted electrons 7 input within a given time is larger, and those signals are processed by the pulse processing unit 9. A control PC 10 has a function of selecting a specific energy region of an energy distribution to display an energy spectrum of the emitted electrons 7 on the basis of data accumulated in the pulse processing unit 9, numerically processing the energy distribution, or displaying only an SEM image depending on the emitted electrons 7 of the energy corresponding to a set energy region. Although not shown in this example, all of components necessary for the SEM such as an aligner used for adjusting the optical axis of the primary electron beam 6, a deflector for scanning the sample 5 with the primary electron beam 6, an image-shift unit that shifts a center position of the primary electron beam on the sample 5, and a stigmator for correcting an astigmatism are included in an SEM column.

Also, in recent years, an aberration correction that corrects a high-order aberration, and a monochrometer that reduces an energy spread of the primary electron beam are also included in the SEM column. Also, a deflection signal may be transmitted from the pulse processing unit 9 to a deflector not shown.

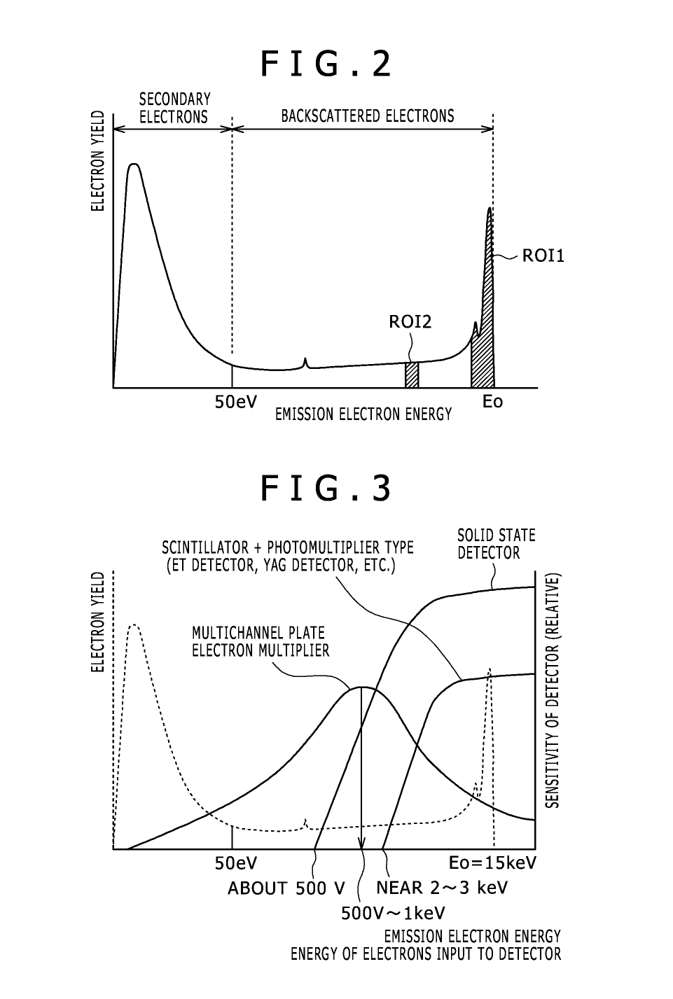

A technique according to the present invention will be described with reference to FIG. 2 illustrating the energy distribution (the axis of abscissa represents the energy of the emitted electrons 7, and the axis of ordinate is the electron yield) of the emitted electrons 7. The energy distribution is distributed in a range corresponding to an irradiation energy Eo of the primary electron beam 6 on the sample 5 from 0 eV. In the range, the emitted electrons 7 from 0 eV to 50 eV are generally called “secondary electrons (SE)”, and the emitted electrons 7 from 50 eV to Eo are generally called “backscattered electrons (BSE)”.

The control PC 10 can set energy regions of interest ROI1 and ROI2 on the obtained energy distribution as illustrated in FIG. 2. Only the SEM image that reflects the number of counts of the emitted electrons 7 in the respective set energy regions can be displayed in the control PC 10. In FIG. 2, the SEM image obtained in the ROI1 is a low loss electron (LLE) image, and the SEM image obtained in the ROI2 is a BSE image that reflects information on a certain specific depth of the sample.

When, for example, two regions are set for the count of the signal, the number of counts obtained in the two regions can be added or subtracted, or added or subtracted by changing a ratio of the number of counts. Also, the number of setting of the region of interest is not limited to two, but any number of setting can be conducted. Further, the pulse processing unit 9 or the control PC 10 can subject the energy distribution to differential processing, and more particularly can enhance a detection sensitivity to a change in a minute energy distribution having specific information.

The SEM can also have a drift correction for correcting a displacement of an acquired image due to a drift of the primary electron beam 6, a stage for moving an observation region of the sample 5 or both. Because it takes time to acquire the image if the number of setting of the region of interest is increased, this drift correction is effective.

In this way, according to the present invention, the same advantages as those of the energy filter combined with the detector 80 are realized by an energy filter with no modification of the detector 80 but the use of an electric signal downstream of the detector 80. That is, the present invention pertains to a method of detecting the input emitted electrons 7 in all of energy regions once, and filtering an energy by the pulse processing unit 9 downstream of the detector 80, which is a novel technique not found in the past SEMs. In the conventional energy filter, the emission energy could not be detected while changing the threshold of the energy distribution at a higher energy side.

In this example, the energy distribution of FIG. 2 does not always match the energy distribution displayed by the control PC 10. This is because the electron yield consistently reflects a state of the electrons immediately after the electrons have been emitted from the sample (that is, an energy distribution diagram when all of the electrons emitted from the sample could be detected), and does not always match the amount of electrons input to the detector 80. The amount of electrons input to the detector is changed according to a detection efficiency (characteristic indicated by the emission energy and the angle, which is generally called “acceptance”), and the characteristic of the detector 80. The former is different according to SEM apparatus manufacturers, and they are elements higher in arbitrary property which are studied by ideas and effects of the respective manufacturers, and therefore are not discussed in the present invention. For that reason, only the characteristic of the detector 80 in the latter will be discussed.

FIG. 3 is a diagram illustrating characteristics of various detectors.

In the detector 80 of the electron microscope, there is used a detector in which a scintillator and a photomultiplier are combined together, which is represented by an Everhart-Thornley (ET) detector or a YAG detector (a light guide for transferring a light may be allocated between the scintillator and the photomultiplier, or an electrode for guiding the emitted electrons to the scintillator with high efficiency may be allocated in front of the scintillator), a silicon PIN type, pn junction type, drift type, or avalanche type solid state detector, a microchannel plate (MCP), or an electron multiplier.

In FIG. 3, an irradiation energy Eo of the primary electron beam 6 is set to 15 keV. A right side of the axis of ordinate represents the energy sensitivity of the detector 80. Normally, the scintillator andscintillator and photomultiplier type detector, and the solid state have a substantially constant sensitivity when the irradiation energy is 10 keV or higher (however, a coating type scintillator depends on a coating thickness, and the electrons input to the scintillator start to go through the scintillator as the energy becomes higher, and the sensitivity gradually decreases. However, when the energy decreases by 5 to 8 keV, the sensitivity rapidly starts to drop, and 2 to 3 keV become a detection limit. However, in the solid state detector, in recent years, the solid state detector in which a surface dead layer is thinned as large as possible, and the detection limit is expanded to about 500 eV become available. Accordingly, in the scintillator and photomultiplier type detector, even if the energy distribution of the emitted electrons ranges from 0 to 15 keV, the energy that can be really detected ranges from 2 to 15 keV, and in the energy of 2 to 8 keV, the number of counts is smaller than the emitted electron quantity. Likewise, in the solid state detector, the energy that can be really detected ranges from 2 to 15 keV, and in the energy of 2 to 8 keV, the number of counts is smaller than the emitted electron quantity. On the other hand, the MCP and the electron multiplier have a peak of sensitivity between 500 eV and 1 keV. The MCP and the electron multiplier are only detectors that can detect the SE with the sensitivity of some degree in this energy region. However, because the sensitivity decreases in the high energy, and the detector is normally located within a vacuum of about 10⁻⁴ Pa, a temporal change in the sensitivity decrease is remarkable, this detector is not positively applied in the marketed conventional SEM.

The present invention is advantageous in that the region of interest can be set even in any energy region within the sensitivity range of the detector. That is, the bandpass of the energy can be detected. For example, in the detector having the energy filter, the threshold of the energy on the higher energy side cannot be made variable, and only the threshold on the lower energy side can be varied. That is, this is a highpass detector of the energy. In the scintillator and photomultiplier type detector and the solid state detector, the threshold on the lower energy side is unambiguously determined according to the energy detection limit of the above-mentioned detector. That is, this is the highpass detection of the energy as with the detector having the energy filter. On the other hand, it is conceivable that the MCP can detect the bandpass from the sensitivity characteristic, but the energy region of the bandpass has no arbitrary property. Therefore, the SEM image obtained by discrimination of the energy is basically smoothed, and reflecting the above-mentioned sample information on the SEM image loses its meaning.

The energy resolution of the detector is determined according to how many carriers are generated by one emitted electron input to the detector in an initial amplification process inside the detector. In this principle, the solid state detector is higher in the energy resolution than the scintillator and photomultiplier type detector, the MCP, and the electron multiplier. The solid state detector manufactured in the present silicon process has the energy resolution (energy resolution of 150 eV at 5 keV) of about 3%. For example, when acquiring a 1% (the energy resolution of 50 eV at 5 keV) LLE image that reflects the surface dead layer and the composition, the solution is insufficient. However, although not illustrated in FIG. 3, in the field of the radiation detection, the development of the superconducting detector that realizes the resolution of 1% or lower is advanced, and if the detector of this type can be applied to the SEM, the present invention has the energy discrimination higher in the general purpose.

From study of FIG. 3, even if the all emitted electrons are captured by the detector, the SE cannot be detected due to the energy detection limit of the respective detectors. That is, only the BSE can be detected. However, in fact, since the ET detector is applied as the SE detector, the SEM has been dramatically developed.

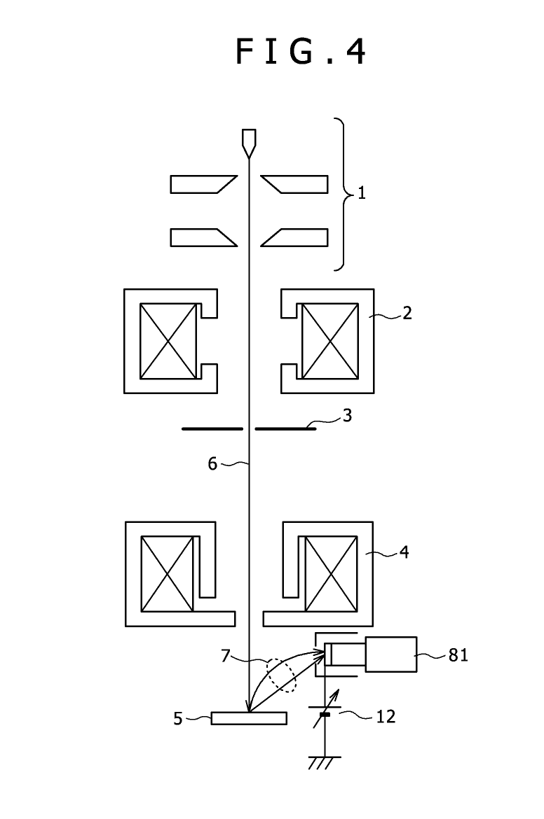

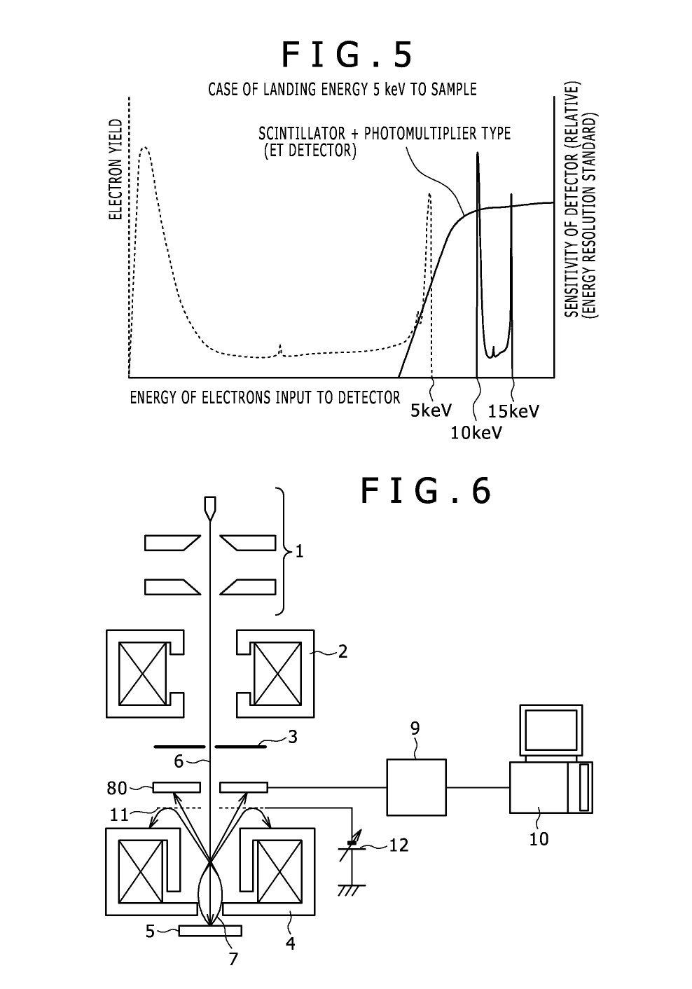

The principle will be described with reference to FIGS. 4 and 5. A detector 81 in FIG. 4 is the ET detector which is generally called “chamber detector”, or “lower detector”, and has a scintillator surface applied with a bias voltage of +10 keV. In this example, the irradiation energy of the primary electron beam 6 to the sample 5 is set to 5 keV. The SE of the emitted electrons 7, which has been emitted in an extensive angle range by an electric field produced by the scintillator, is detected by the scintillator. The energy of the SE input to the scintillator ranges from 10 keV to 10.050 keV. On the other hand, the BSE is higher in the original radiation energy, and therefore is not affected by the electric field produced by the scintillator. Substantially only the BSE emitted from an irradiation point of the primary electron beam 6 on the sample 5 at a solid angle making an allowance for the detector 8 is detected by the scintillator. The energy of the BSE input to the scintillator ranges from 10.050 keV to 15 keV. A relationship of the energy indicative of this state, the electron yield, and the energy sensitivity of the ET detector is illustrated in FIG. 5. That is, the energy distribution from the original 0 to 5 keV is shifted to the energy distribution from 10 keV to 15 keV, and in this energy region, the sensitivity of the ET detector is sufficient. Therefore, if the region of interest is set in the energy region from 10 keV to 15 keV, the separation of the SE and the BSE can be conducted in principle. However, as described above, the threshold of the region of interest has a range depending on the energy resolution of the detector, the energy resolution of the present solid state detector cannot completely separate the SE and the BSE. In recent years, an extremely low acceleration voltage observation having the irradiation energy of 1 keV or lower is mainstream even in the SEM. In particular, when the irradiation energy is lower than 500 eV, the SE and the BSE are not distinguished from each other, a case where there is no need to completely distinguish the SE and the BSE from each other should be assumed.

So far as the present solid state detector or the scintillator and photomultiplier type detector are used, the energy resolution is limited. However, the present invention is excellent in that the threshold of the higher energy can be varied. Therefore, it is effective to the energy shift and the energy filter together as described in FIGS. 4 and 5, and the energy resolution of 1% or lower can be realized according to the design.

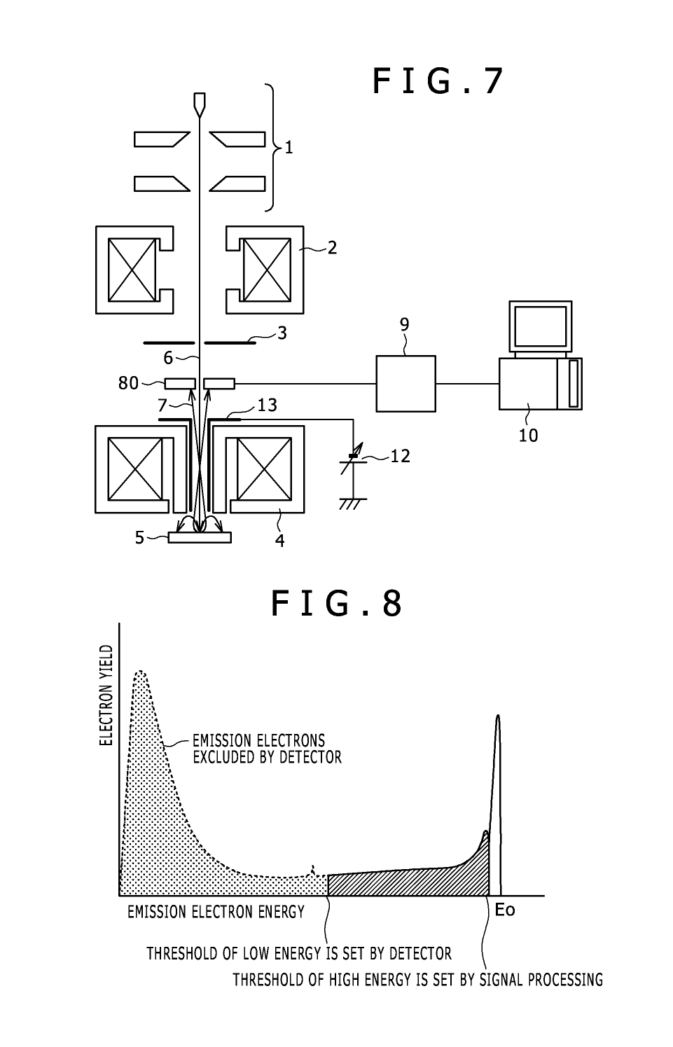

FIG. 6 illustrates an example in which the detector 80 and an energy filter 11 are located coaxially with the optical axis of the primary electron beam 6, and the pulse processing unit 9 and the control PC 10 are connected to each other to the detector 80. A negative bias voltage 12 relative to the sample voltage potential is applied to the energy filter 11. The emitted electrons 7 having an energy that cannot exceed a potential barrier produced by the bias voltage 12 are turned backed by the filter. The emitted electrons 7 having an energy that has exceeded the potential barrier decelerate its energy to the potential barrier produced by the filter once, but accelerate the energy to an original energy after having passed through the filter, and are detected by the detector 80. FIG. 7 illustrates the objective lens 4 (semi-in-lens) of the type which aggressively leaks a magnetic field to the sample side to obtain a high resolution SEM image, in which an electrode 13 is located in the objective lens 4 coaxially with the optical axis of the primary electron beam 6, and the negative bias voltage is applied to the sample voltage potential. The emitted electrons 7 having the energy that cannot exceed a potential barrier produced by the bias voltage 12 are turned backed by the electrode. The emitted electrons 7 having the energy that has exceeded the potential barrier decelerates its energy to the potential barrier produced by the electrode once, but accelerates the energy to the original energy after having passed through the filter, and are detected by the detector 80.

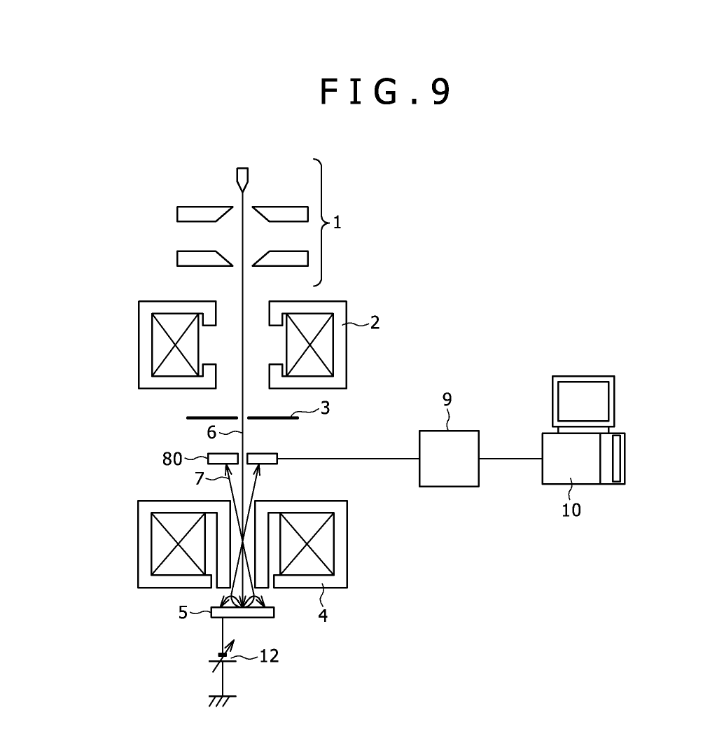

The energy distributions of the emitted electrons 7 that can be detected by FIGS. 6 and 7 can be described with reference to FIG. 8. The energy of the primary electron beam 6 on the sample 5 is Eo, and the energy is lost once before the emitted electrons 7 arrive at the detector. However, because the primary electron beam 6 are finally accelerated to the original energy, there is no energy shift, and the emitted electrons 7 low in the energy are excluded by the detection system (the energy filter in FIG. 6, the electrode in FIG. 7). Therefore, this is equivalent to setting of the threshold of the low energy by the detection system. On the other hand, because the threshold of the high energy can be set by the pulse processing unit 9 and the control PC 10, only the emitted electrons 7 having an energy of a portion blacked out in FIG. 8 can be visualized as the SEM image.

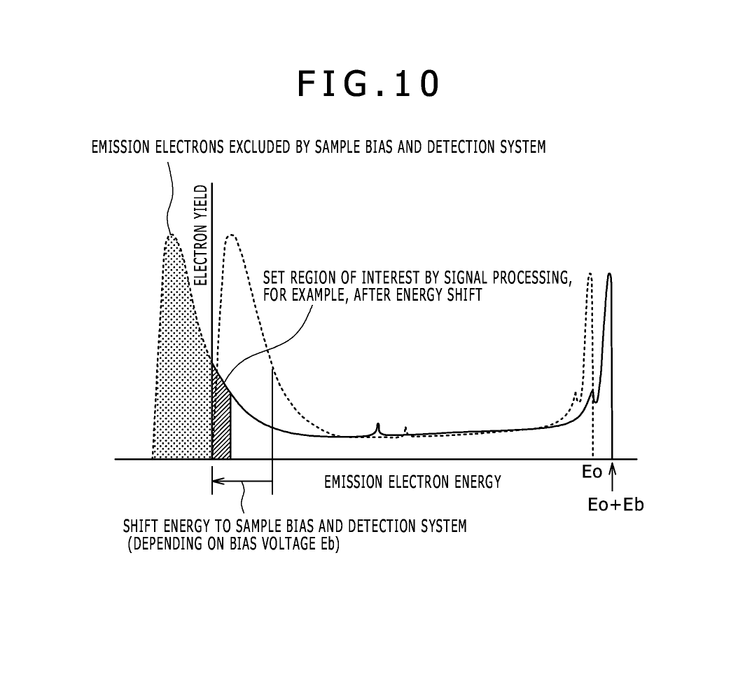

FIG. 9 illustrates an example in which the detector 80 is located coaxially with the optical axis of the primary electron beam 6 upstream (electron gun 1 side) of the objective lens 4, in which the pulse processing unit 9 and the control PC 10 are connected to the detector 80, and the positive bias voltage 12 is applied to the sample 5. The energy distribution of the emitted electrons 7 that can be detected in FIG. 9 can be described with reference to FIG. 10. The irradiation energy of the primary electron beam 6 on the sample 5 is a sum of Eo and a voltage potential Eb produced by the bias voltage 12. On the other hand, the distribution of the emitted electrons 7 shifted to the minus side with respect to 0 eV in FIG. 10 are actually electrons not emitted from the sample which have been generated within the sample 5, and cannot exceed the potential barrier of Eb. Therefore, this is equivalent to setting of the threshold of the low energy side. However, when this example is applied to the BSE, because the irradiation energy of the primary electron beam 6 on the sample 5 becomes larger, this example is not applied to observation for a shallow surface of the smaple 5 at the low acceleration voltage. Therefore, the system of FIG. 9 is suitable to be combined with the detection system that can shift the energy as illustrated in FIG. 5, cut the BSE on the higher energy side by the pulse processing unit 9 and the control PC, and control the detection energy region of the SE so as to reflect the potential contrast of the sample 5 surface.

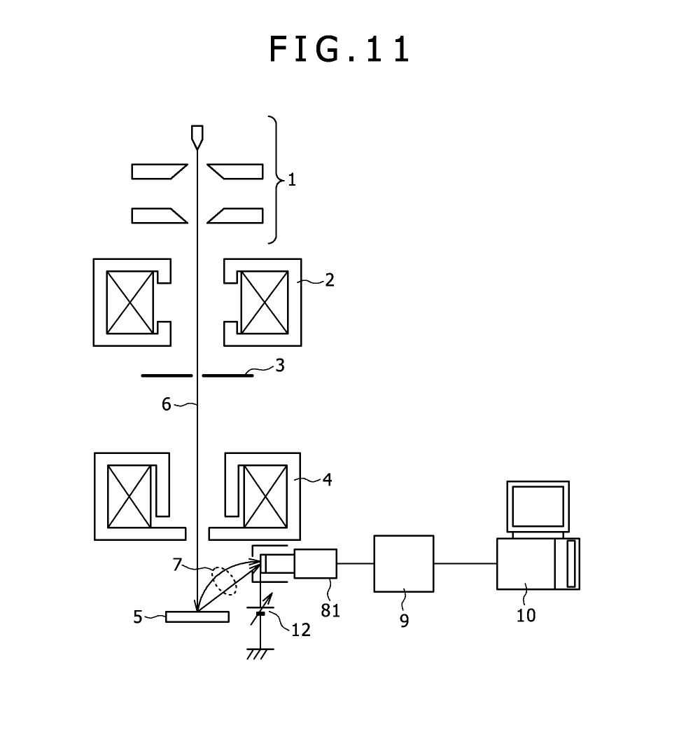

FIG. 11 illustrates an example in which the pulse processing unit 9 and the control PC 10 are connected to the detector 80 of FIG. 4. As described in FIG. 5, this example has an action of shifting the energy distribution to the higher energy side by a potential of the bias voltage 12 applied to the scintillator.

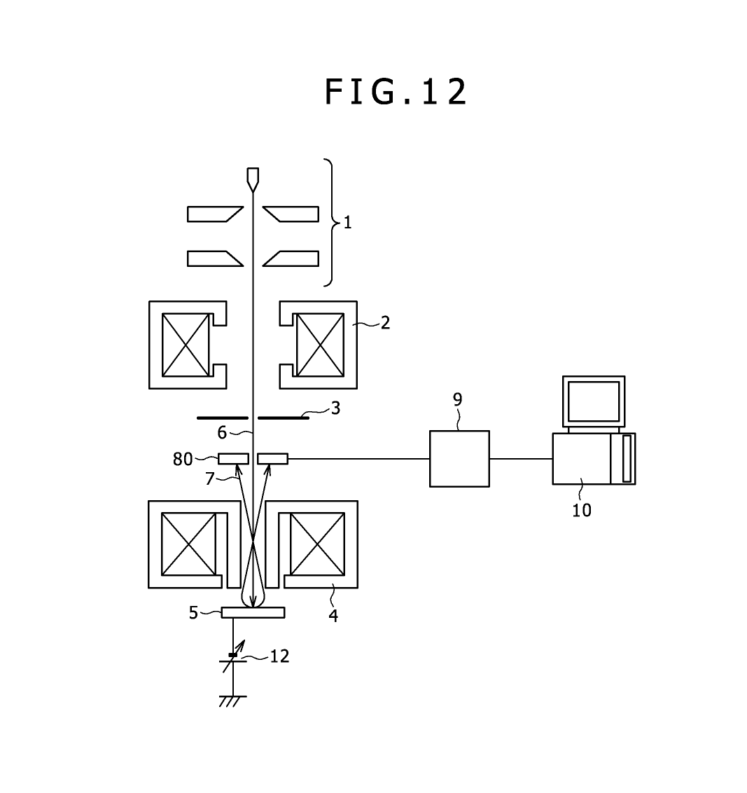

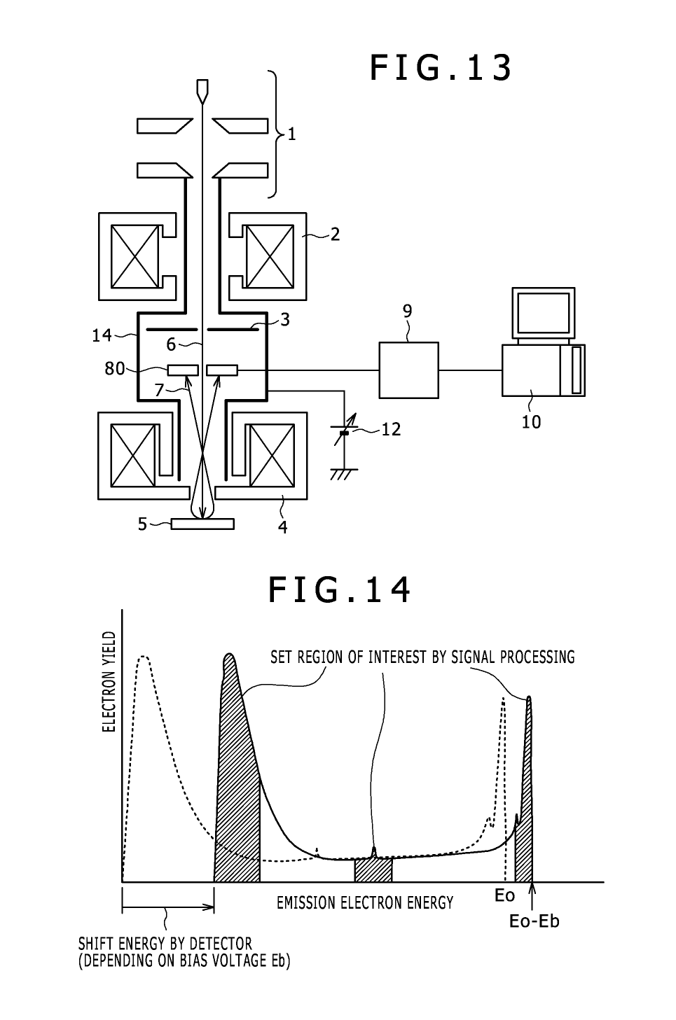

FIG. 12 illustrates the objective lens 4 of the type which positively leaks a magnetic field to the sample side to obtain a high resolution SEM image, in which the detector 80 is located coaxially with the optical axis of the primary electron beam 6 upstream (electron gun 1 side) of the objective lens 4, and the pulse processing unit 9 and the control PC 10 are connected to the detector 80. The sample 5 is applied with the negative bias voltage 12 for realizing the high resolution SEM image at a low acceleration voltage generally called “deceleration”. With this bias voltage 12, the emitted electrons 7 is accelerated in an upstream direction of the objective lens 4, and input to the detector 80. Therefore, as in FIG. 11, this example has an action of shifting the energy distribution to the higher energy side. FIG. 13 illustrates an example in which a beam booster electrode 14 for accelerating the primary electron beam 6 once immediately after having passed through the electron gun 1, and decelerating the primary electron beam 6 immediately before passing through the objective lens 4 is located coaxially on the optical axis of the primary electron beam 6, the positive bias voltage 12 is applied to the beam booster electrode, the detector 80 is located in the potential of the bias voltage 12, and the pulse processing unit 9 and the control PC 10 are connected to the detector 80. With this bias voltage 12, the emitted electrons 7 are accelerated in the upstream direction immediately after having entered the objective lens 4, and input to the detector 80. Therefore, as in FIGS. 11 and 12, this example also has an action of shifting the energy distribution to the higher energy side.

The energy distributions of the emitted electrons 7 that can be detected in FIGS. 11, 12, and 13 can be described in FIG. 14. The energy of the primary electron beam 6 on the sample 5 in FIGS. 11 and 13 is Eo, and the irradiation energy of the primary electron beam 6 on the sample 5 in FIG. 12 is a sum of Eo and the potential Eb produced by the bias voltage 12 (because Eb is a negative potential, the energy becomes lower than Eo). In all of FIGS. 11, 12, and 13, in a state where the emitted electrons 7 arrive at the detector 80 or the detector 81, the energy distribution is shifted to the higher energy side by the bias voltage Eb. If the shift of the energy distribution is larger than the sensitivity limit of the detector 80 or the detector 81, the region of interest is set by the pulse processing unit 9 and the control PC 10, and for example, only the emitted electrons 7 having the energy of a portion blacked out in FIG. 14 can be visualized as the SEM image.

It can be easily conceived that there are conditions in which the detectors and the electrode arrangement, and the bias voltage application method illustrated in FIGS. 1, 6, 7, 9, 11, 12, and 13 can be operated in combination, and also not only one detector but also two or more detectors can be operated in combination.

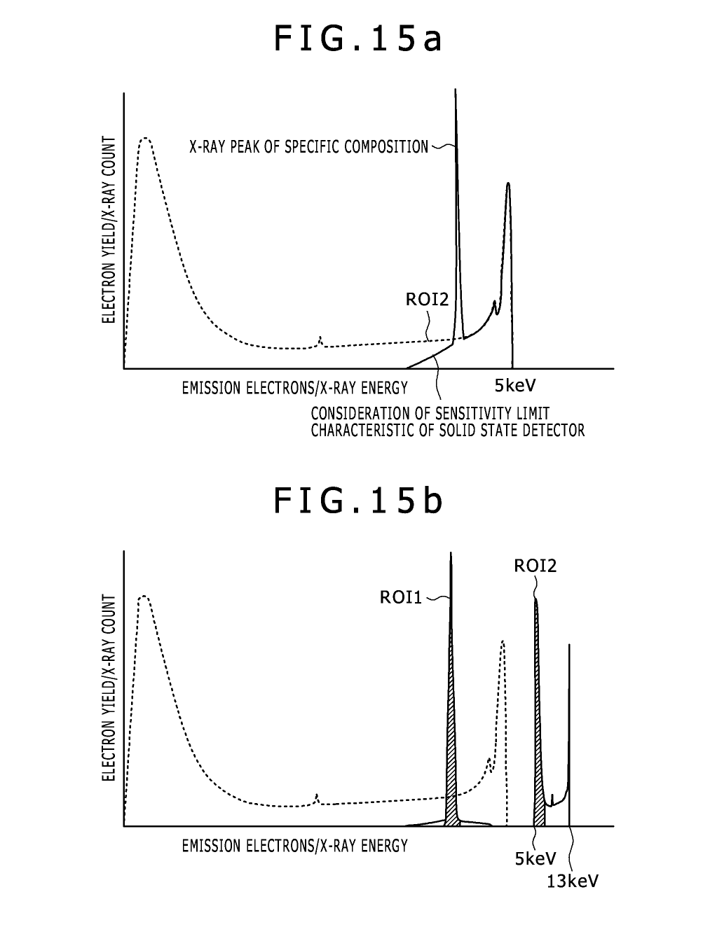

The detection of the SE or the BSE has been described above. When the detector 80 is the solid state detector or the superconducting detector, the characteristic x-ray that reflects the composition of the sample 5 generated by an interaction of the primary electron beam 6 and the sample 5 can be detected depending on the manufacture condition of the detector element. In this condition, the energy distribution illustrated in FIG. 15A is obtained. The region of interest can be set by this energy distribution. However, if a detection system of FIG. 13 is used, an energy distribution illustrated in FIG. 15B can be obtained. Because the x-ray is not affected by the electric field, the energy shift is not generated. In this example, the irradiation energy Eo of the primary electron beam 6 on the primary electron beam 6 is 5 keV, and the bias voltage 12 to the beam booster electrode 13 is 8 keV. Normally, in an interaction volume depending on the irradiation energy Eo of the primary electron beam 6 inside the sample 5, because the x-ray and the BSE are generated particularly in the deepest portion, and an energy of some degree is required for an x-ray excitation, the irradiation energy Eo of the primary electron beam 6 on the sample 5 generally needs to be set to 5 keV or higher. When the sample 5 is silicon, the primary electron beam 6 arrives at an interior portion of 500 nm inside the sample 5. Therefore, a mapping image of the BSE or the x-ray reflects information inside the sample, but does not reflect the sample surface. However, in fact, there are a lot of applications that want to obtain composition information in a shallow region of 100 nm or lower. On the other hand, the SE low in the energy is generated from a shallow surface region of normally tens of nm, but does not reflect the compositional information. Under the circumstance, if the energy distribution illustrated in FIG. 15B can be obtained, ROI1 is set for a peak of the characteristic x-ray, and ROI2 is set for a portion of the SE in the energy-shifted emitted electron distribution, and an image that reflects only a signal counted in the ROI2 can be displayed only when the count is present in the ROI1, a mapping image including information on the composition and the surface can be acquired. It is needless to say that the ROI2 may be set in only the SE but also a specific energy region, and the ROI1 can be set for one or more peaks.

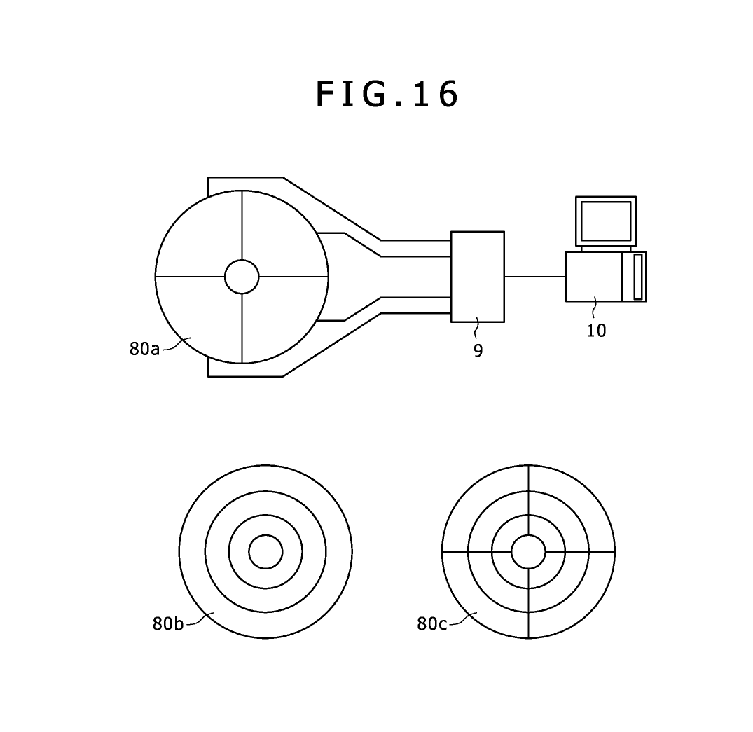

The angle distribution of the emitted electrons 7 is also an important element for obtaining necessary information. For example, in FIG. 1, in the angle distribution, the angle range of the detectable emitted electrons 7 is determined according to a distance between the detector 80 and the sample 5. When, for example, a distance from a bottom of the objective lens 4 to the sample 5 called “working distance (WD)” is changed, the angle range is also variable. Also, in FIGS. 6, 7, 9, 12, and 13, when the emitted electrons 7 passes through a lens field of the objective lens 4, because the emitted electrons 7 is subjected to focus action as with the primary electron beam 6, an orbit of the emitted electrons 7 is spread depending on the emission angle over the sample 5 when the emitted electrons 7 arrives at the detector 80. The angle range can be also changed with the use of this spread. Except that the angle range is set under an electron optics condition, a detection surface of the detector 80 arranged coaxially with the optical axis of the primary electron beam 6 can be divided as illustrated in FIG. 16. The detection surface of the detector 80 can be divided on a circumference (80a), divided coaxially (80b), and divided circumferential coaxially (80c). Electric signals generated by the emitted electrons 7 detected by the respective detection areas are transmitted to the pulse processing unit 9 and the control PC 10 so as to acquire the energy distributions for the respective detection surfaces. The angle of the emitted electrons 7 can be discriminated in a limited range by the electron optics condition change and the division of the detection surface of the detector 80. Also, if the energy can be discriminated by the detection system, the pulse processing unit 9, and the control PC 10, the emitted electrons 7 can be detected by increased options, and the sample surface or the topographic information, the sample internal information, the voltage potential information on the sample surface, the compositional or crystalline information on the sample, and the sample internal information can selectively extracted. Even in the detector not arranged on the optical axis of the primary electron beam 6 as illustrated in FIG. 11, the arrangement space is proprietary, but when two or more detectors are arranged circumferentially about the optical axis, the angle options such as 80a can be realized.

The SEM has been mainly described above. However, the present invention can be applied to not only the SEM, but a complex charged particle beam apparatus that processes the sample 5 with the use of one or more ion beams to form an observation cross-section, and that the cross-section is observed by SEM, or a scanning transmission electron microscope (STEM) using the primary electron beam 6 of a high energy of the degree that passes through the sample 5, or signal detection of the SE, the BSE, or transmission electrons (TE). Also, in the STEM, there is an EELS analysis that measures an energy loss distribution of transmission electrons to obtain specific elements or compositional information. The marketed EELS device is very expensive and large in size. However, with the application of the present invention, inexpensive and downsized EELS device can be realized.

### LIST OF REFERENCE SIGNS

1 electron gun
2 condenser lens
3 aperture
4 objective lens
5 sample
6 primary electron beam
7 emitted electrons
9 pulse processing unit
10 control PC
11 energy filter
12 bias voltage
13 electrode
14 beam booster electrode
80, 81 detector

1. A charged particle beam apparatus having a charged particle source that emits a primary charged particle beam, a condenser lens that condenses the primary charged particle beam on a sample, and a detector that detects secondary charged particles emitted from a radiated point on the sample, the charged particle beam apparatus comprising:
a pulse processing unit that detects the secondary charged particles in an energy region detectable by the detector, subjects a signal from the detector to pulse processing, and creates energy distribution information of the secondary charged particles; and a control unit that forms an image with the use of only information in an arbitrary energy region selected from the energy distribution information, and display the image on a display unit.

2. The charged particle beam apparatus according to claim 1, comprising: a second charged particle source different from the charged particle source, wherein the sample is irradiated with a charged particle beam from the second charged particle source.

3. The charged particle beam apparatus according to claim 1,
wherein the control unit can select at least two energy regions, and superimposes signals corresponding to the respective energy regions on each other to display the image on the display unit.

4. The charged particle beam apparatus according to claim 1,
wherein the pulse processing unit acquires an energy distribution subjected to differential processing.

5. The charged particle beam apparatus according claim 3, wherein an image in which the signals of a plurality of energy regions selected by the control unit are superimposed on each other with a change in a signal ratio is displayed.

6. The charged particle beam apparatus according to claim 1,
wherein the detector has a function of also detecting a characteristic X-ray generated by an interaction of the primary charged particle beam and the sample, sets an energy region corresponding to a specific X-ray, and an arbitrary energy region of the secondary charged particles, and displays, only when a signal is present in the set energy region of the X-ray, displays information on the secondary charged particles in the set energy region as an image.

7. The charged particle beam apparatus according to claim 1,
wherein the detector comprises one of a PIN photodiode, a PN junction photodiode, an avalanche photodiode, and a silicon drift element.

8. The charged particle beam apparatus according to claim 1,
wherein the detector comprises a scintillator and a photomultiplier.

9. The charged particle beam apparatus according to claim 1,
wherein the detector comprises one of a microchannel plate and a photomultiplier.

10. The charged particle beam apparatus according to claim 1,
wherein the detector comprises a superconducting detector element.

11. The charged particle beam apparatus according to claim 1,
wherein the detector is divided into detection areas in a coaxial and/or circumferential direction, and signals from the respective detection areas are processed by the pulse processing unit.

12. The charged particle beam apparatus according to claim 1,
wherein the detector includes an energy filter that sets a threshold of an energy distribution of the secondary charged particles on a lower energy side.

13. The charged particle beam apparatus according to claim 1, comprising a stage on which the sample is placed, and a power supply that applies a voltage to the stage.

14. The charged particle beam apparatus according to claim 1,
wherein an electrode is allocated coaxially with the primary charged particle beam trajectory axis, and a power supply that applies a voltage to the electrode is provided.
